(19) United States
(12) Patent Application Publication
(10) Pub. No.: US 2009/0108343 A1
(43) Pub. Date: Apr. 30, 2009

(54) SEMICONDUCTOR COMPONENT AND METHOD OF MANUFACTURE

(76) Inventors: Gennadiy Nemtsev, Stoughton, MA (US); Hui Wang, East Greenwich, RI (US); Yingping Zheng, East Greenwich, RI (US); Gordon M. Grivna, Mesa, AZ (US)

Correspondence Address: SEMICONDUCTOR COMPONENTS INDUSTRIES, LLC;INTELLECTUAL PROPERTY DEPT. - A700, 5005 E. MCDOWELL ROAD, P.O.BOX 62890, PHOENIX, AZ, 85082, US

(21) Appl. No.: 11/931,994

(22) Filed: Oct. 31, 2007

(51) Int. Cl. H01L 29/78; H01L 21/336

(52) U.S. Cl. 257/330; 438/270; 257/E21.41; 257/E29.262

(57) ABSTRACT

A semiconductor component that includes a field plate and a semiconductor device and a method of manufacturing the semiconductor component. A semiconductor material includes an epitaxial layer disposed on a semiconductor substrate. Field plate trenches extend into the semiconductor material and field plates are formed in the field plate trenches. A gate trench is formed between two adjacent field plate trenches and another gate trench is formed adjacent one of the field plate trenches. Gate structures are formed in the gate trenches, wherein each gate structure includes a gate oxide and a gate conductor. A conductor electrically couples the field plates together.

### TECHNICAL FIELD

The present invention relates, in general, to semiconductor components and, more particularly, to power switching semiconductor components.

### BACKGROUND

Metal-Oxide Semiconductor Field Effect Transistors (“MOSFETs”) are a common type of power switching device. A MOSFET device includes a source region, a drain region, a channel region extending between the source and drain regions, and a gate structure provided adjacent to the channel region. The gate structure includes a conductive gate electrode layer disposed adjacent to and separated from the channel region by a thin dielectric layer. When a voltage of sufficient strength is applied to the gate structure to place the MOSFET device in an on state, a conduction channel region forms between the source and drain regions thereby allowing current to flow through the device. When the voltage that is applied to the gate is not sufficient to cause channel formation, current does not flow and the MOSFET device is in an off state.

Today's high voltage power switch market is driven by two major parameters: breakdown voltage (“BVdss”) and on-state resistance (“Rdson”). For a specific application, a minimum breakdown voltage is required, and in practice, designers typically can meet a BVdss specification. However, this is often at the expense of Rdson. This trade-off in performance is a major design challenge for manufacturers and users of high voltage power switching devices. Another challenge arises because Power MOSFET devices have an inherent P-N diode between a P-type conductivity body region and an N-type conductivity epitaxial region. This inherent P-N diode turns on under certain operating conditions and stores charge across the P-N junction. When a sudden reverse bias is applied to the P-N diode, the stored charge produces a negative current flow until the charge is completely depleted. The time for the charge to become depleted is referred to as the reverse recovery time (“Trr”) and delays the switching speed of the power MOSFET devices. In addition, the stored charge (“Qrr”) causes a loss in the switching voltage levels due to the peak reverse recovery current (“Irr”) and the reverse recovery time.

Accordingly, it would be advantageous to have a semiconductor component that has a lower Rdson with a higher breakdown voltage and lower switching losses, i.e., lower Qrr losses, and a method for manufacturing the semiconductor component. It would be of further advantage for the semiconductor component to be cost efficient to manufacture.

### BRIEF DESCRIPTION OF THE DRAWINGS

The present invention will be better understood from a reading of the following detailed description, taken in conjunction with the accompanying drawing figures, in which like reference numbers designate like elements and in which:

FIG. 1 is a cross-sectional view of a semiconductor component at an early stage of manufacture in accordance with an embodiment of the present invention;

FIG. 2 is a cross-sectional view of the semiconductor component of FIG. 1 at a later stage of manufacture;

FIG. 3 is a cross-sectional view of the semiconductor component of FIG. 2 at a later stage of manufacture;

FIG. 4 is a cross-sectional view of the semiconductor component of FIG. 3 at a later stage of manufacture;

FIG. 5 is a cross-sectional view of the semiconductor component of FIG. 4 at a later stage of manufacture;

FIG. 6 is a cross-sectional view of the semiconductor component of FIG. 5 at a later stage of manufacture;

FIG. 7 is a cross-sectional view of the semiconductor component of FIG. 6 at a later stage of manufacture;

FIG. 8 is a cross-sectional view of the semiconductor component of FIG. 7 at a later stage of manufacture;

FIG. 9 is a cross-sectional view of the semiconductor component of FIG. 8 at a later stage of manufacture;

FIG. 10 is a cross-sectional view of the semiconductor component of FIG. 9 at a later stage of manufacture;

FIG. 11 is a cross-sectional view of the semiconductor component of FIG. 10 at a later stage of manufacture;

FIG. 12 is a cross-sectional view of the semiconductor component of FIG. 11 at a later stage of manufacture;

FIG. 13 is a cross-sectional view of the semiconductor component of FIG. 12 at a later stage of manufacture;

FIG. 14 is a cross-sectional view of a semiconductor component in accordance with another embodiment of the present invention;

FIG. 15 is a cross-sectional view of a semiconductor component at an intermediate stage of manufacture in accordance with another embodiment of the present invention;

FIG. 16 is a cross-sectional view of the semiconductor component of FIG. 15 at a later stage of manufacture;

FIG. 17 is a cross-sectional view of the semiconductor component of FIG. 16 at a later stage of manufacture;

FIG. 18 is a cross-sectional view of the semiconductor component of FIG. 17 at a later stage of manufacture;

FIG. 19 is a cross-sectional view of the semiconductor component of FIG. 18 at a later stage of manufacture;

FIG. 20 is a cross-sectional view of the semiconductor component of FIG. 19 at a later stage of manufacture;

FIG. 21 is a cross-sectional view of the semiconductor component of FIG. 20 at a later stage of manufacture; and

FIG. 22 is a cross-sectional view of the semiconductor component of FIG. 21 at a later stage of manufacture.

### DETAILED DESCRIPTION

Generally, the present invention provides a semiconductor component that includes a field plate and a semiconductor device such as a field effect transistor or a trench field effect transistor, a vertical power field effect transistor, a power field effect transistor, or combinations thereof. It should be noted that a power field effect transistor is also referred to as a vertical power device and a vertical field effect transistor is also referred to as a power device. In accordance with an embodiment, a semiconductor component includes a plurality of field plate trenches formed in a semiconductor material comprising a layer of epitaxial material disposed over a semiconductor substrate. The plurality of field plate trenches have sidewalls and a floor that are lined with a dielectric material. An electrically conductive material is formed on the dielectric material in the trenches. A gate trench having sidewalls and a floor is formed between two adjacent field plate trenches. A gate dielectric material such as, for example, a gate oxide is formed in the gate trench and a gate conductor is formed on the gate dielectric. Thus, the gate trench is lined with a dielectric material.

In accordance with another embodiment, gate trenches are formed laterally adjacent to and spaced apart from the field plate trenches. A gate dielectric material such as, for example, a gate oxide is formed in the gate trenches and a gate conductor is formed on the gate dielectric.

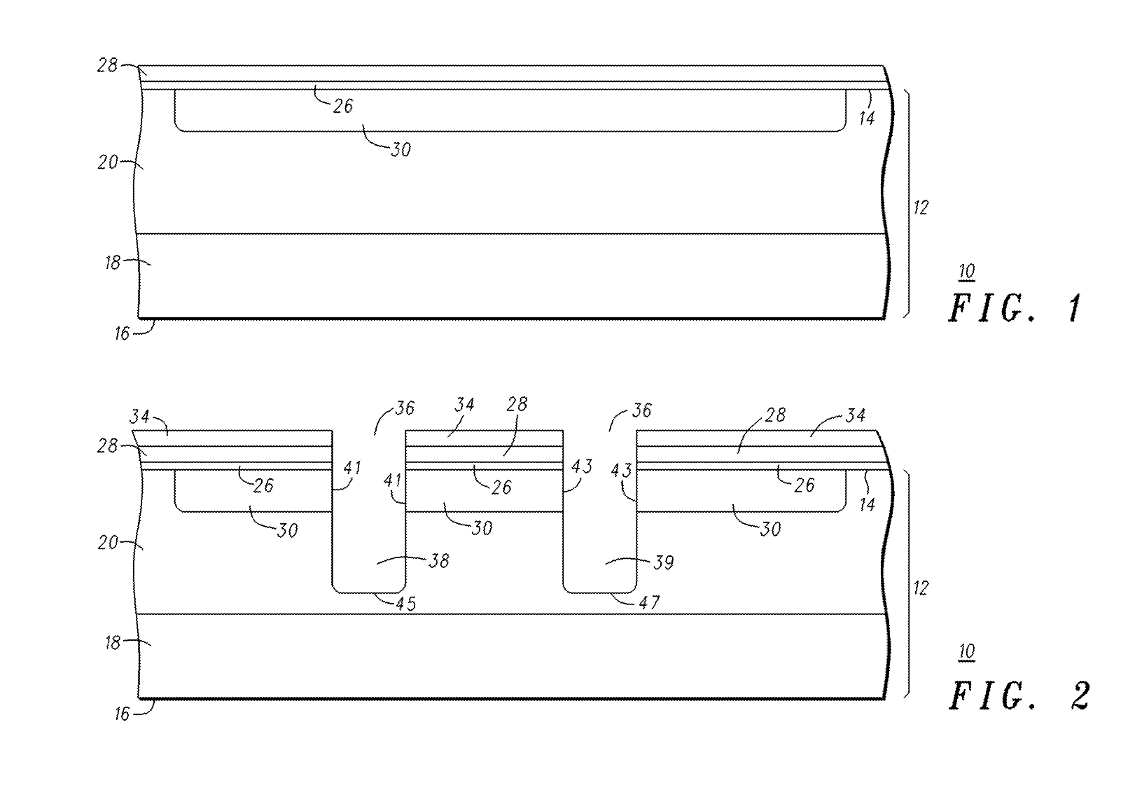

FIG. 1 is a cross-sectional view of a portion of a semiconductor component 10 during manufacture in accordance with an embodiment of the present invention. What is shown in FIG. 1 is a semiconductor material 12 having opposing surfaces 14 and 16. Surface 14 is also referred to as a front or top surface and surface 16 is also referred to as a bottom or back surface. In accordance with an embodiment, semiconductor material 12 comprises an epitaxial layer 20 that is disposed on a semiconductor substrate 18. Preferably, substrate 18 is silicon that is heavily doped with an N-type dopant or impurity material and epitaxial layer 20 is silicon lightly doped with an N-type dopant. The resistivity of substrate layer 18 may be less than about 0.01 Ohm-centimeters (“Ω-cm”) and the resistivity of epitaxial layer 20 may be greater than about 0.1 Ω-cm. Substrate layer 18 provides a low resistance conduction path for the current that flows through a power transistor and a low resistance electrical connection to a bottom drain conductor that is formed on bottom surface 16 of semiconductor material 12, a top drain conductor, or both. A region or layer doped with an N-type dopant is referred to as having an N-type conductivity or an N conductivity type and a region or layer doped with a P-type dopant is referred to as having a P-type conductivity or a P conductivity type.

A layer of dielectric material 26 is formed on or from epitaxial layer 20. In accordance with an embodiment, the material of dielectric layer 26 is silicon dioxide having a thickness ranging from about 200 Angstroms (Å) to about 1,000 Å. Techniques for forming silicon dioxide layer 26 are known to those skilled in the art. An implant mask (not shown) is formed on dielectric layer 26. By way of example, the implant mask is photoresist having openings that expose portions of dielectric layer 26. A P-type conductivity dopant layer (not shown) is formed in epitaxial layer 20. The dopant layer may be formed by implanting an impurity material such as, for example, boron into epitaxial layer 20. By way of example, the boron is implanted at a dose ranging from about 1×10¹³ ions per centimeter squared (ions/cm²) to about 1×10¹⁴ ions/cm², and an implant energy ranging from about 100 kilo electron volts (keV) to about 400 keV. The technique for forming the dopant layer is not limited to an implantation technique. The masking structure is removed.

A protective layer 28 is formed on dielectric layer 26. Protective layer 28 may be silicon nitride having a thickness ranging from about 500 Å to about 2,000 Å. Dielectric layer 26 may have a thickness of about 300 Å and protective layer 28 may have a thickness of about 1,000 Å. Preferably, the materials of layers 26 and 28 are selected so that protective layer 28 restricts oxygen diffusion and therefore protects underlying layers from oxidation. Although protective layer 28 is shown as a single layer of material, it can also be a multi-layered structure of different material types. Epitaxial layer 20 is annealed by heating to a temperature ranging from about 1,000 Degrees Celsius (° C.) to about 1,200° C. Annealing epitaxial layer 20 drives in the impurity material of the dopant layer creating a doped region 30.

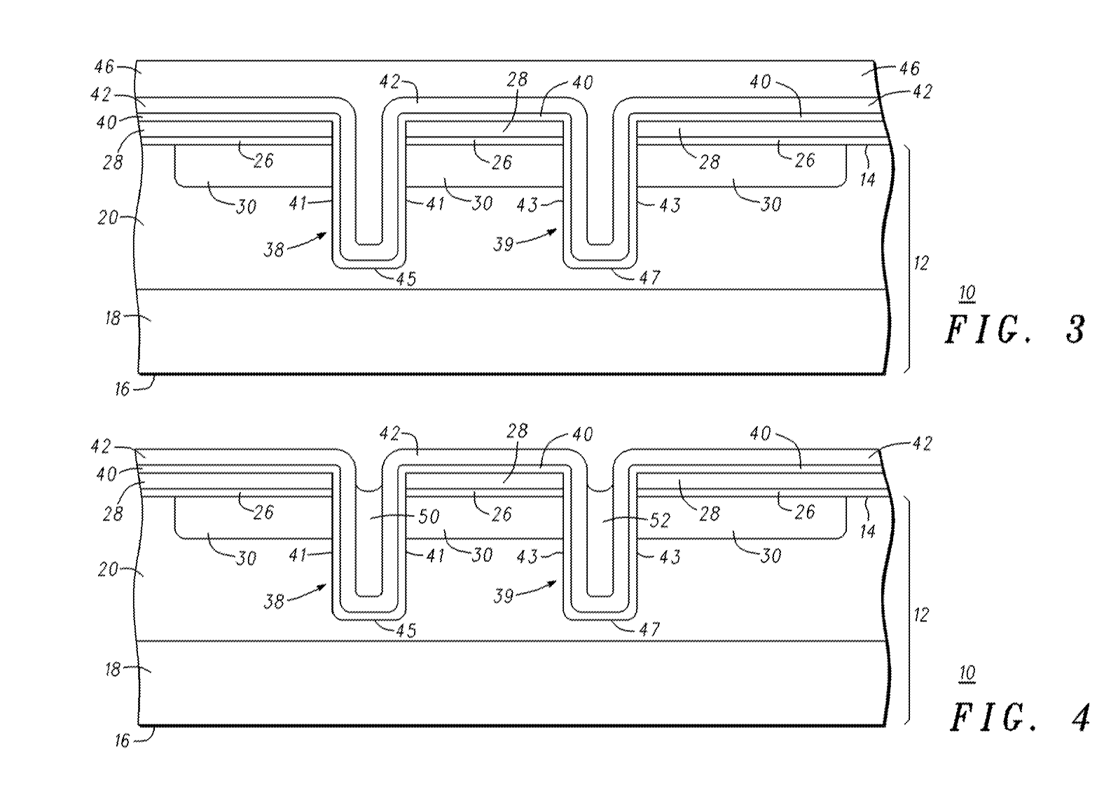

Referring now to FIG. 2, a layer of photoresist is patterned over protective layer 28 to form a masking structure 34 having openings 36 that expose portions of protective layer 28. Masking structure 34 is also referred to as a mask. Trenches 38 and 39 having sidewalls 41 and 43, and floors 45 and 47, respectively, are formed in epitaxial layer 20 by removing portions of protective layer 28, dielectric layer 26, and epitaxial layer 20. More particularly, the exposed portions of protective layer 28 and the portions of dielectric layer 26 and epitaxial layer 20 that are below the exposed portions of protective layer 28 are removed. These portions of layers 28, 26, and 20 may be removed using an anisotropic etch technique such as, for example, reactive ion etching. Although trenches 38 and 39 are shown as ending in epitaxial layer 20, this is not a limitation of the present invention. For example, trenches 38 and 39 may extend into substrate 18. The etching technique and the number of trenches formed in epitaxial layer 20 are not limitations of the present invention. Because field plates will be formed in trenches 38 and 39, they may be referred to as field plate trenches. Masking structure 34 is removed.

Referring now to FIG. 3, a sacrificial layer of dielectric material 40 having a thickness ranging from about 250 Å to about 1,250 Å is formed along sidewalls 41 and 43 and floors 45 and 47 of the respective trenches 38 and 39. A layer of dielectric material 42 having a thickness ranging from about 5,000 Å to about 15,000 Å is formed on sacrificial layer 40 and protective layer 28. Thus, dielectric material 42 is formed to be laterally adjacent to sidewalls 41 and 43 and vertically adjacent to protective layer 28 and floors 45 and 47. Dielectric layer 42 may be formed or deposited by decomposition of tetraethylorthosilicate. A dielectric layer formed in this fashion is also referred to as a TEOS layer. Dielectric layer 42 is annealed by heating to a temperature ranging from about 500° C. to about 1,500° C. In embodiments in which semiconductor components are capable of sustaining voltages of greater than about 250 volts, another layer of dielectric material (not shown) such as, for example, a TEOS layer, having a thickness ranging from about 5,000 Å to about 15,000 Å is formed on dielectric layer 42. Like dielectric layer 42, dielectric material 40 is formed to be laterally adjacent to sidewalls 41 and 43 and vertically adjacent to protective layer 28 and floors 45 and 47. It should be noted that forming a layer of dielectric material on dielectric layer 42 is optional. A doped layer of semiconductor material 46 such as, for example, polysilicon having a dopant or impurity material concentration ranging from about 1×10¹⁹ atoms per cubic centimeter (atoms/cm³) to about 1×10²¹ atoms/cm³ and a thickness ranging from about 5,000 Å to about 15,000 Å is formed on dielectric layer 42. In accordance with an embodiment of the present invention, sacrificial layer 40 has a thickness of about 670 Å, dielectric layer 42 and the optional layer of dielectric material each have thicknesses of about 9,000 Å, and polysilicon layer 46 has a thickness of about 8,000 Å and is doped with an impurity material of N-type conductivity having a concentration of about 2×10²⁰ atoms/cm³. Thus, portions of semiconductor layer 46 are between the dielectric material that is adjacent to sidewalls 41 and 43 of trenches 38 and 39.

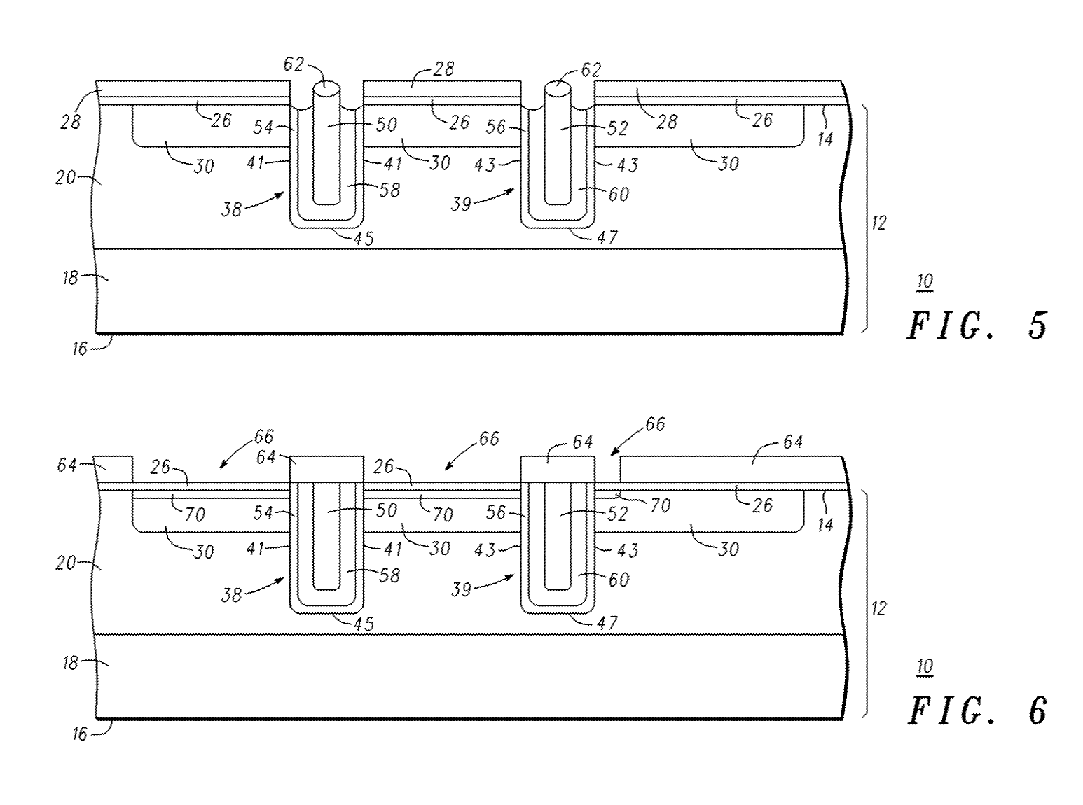

Referring now to FIG. 4, polysilicon layer 46 is etched using a blanket polysilicon etchback process, leaving TEOS layer 42 and portions 50 and 52 of polysilicon layer 46, in trenches 38 and 39, respectively. Portions 50 and 52 of polysilicon layer 46 are referred to as field plates.

Referring now to FIG. 5, the exposed portions of dielectric layer 42 are etched using, for example, a reactive ion etch. The remaining portions of dielectric layer 42, i.e., portions 54, 56, 58, and 60, are cleaned using, for example, a wet etching solution comprising ten parts hydrofluoric acid to one part water. Because of the composition of the wet etching solution, this cleaning step may be referred to as a ten-to-one oxide wet dip. After cleaning, portions 54 and 56 of dielectric layer 40 and portions 58 and 60 of dielectric layer 42 remain in trenches 38 and 39, respectively. In addition, portions 50 and 52 of polysilicon layer 46 remain in trenches 38 and 39, respectively.

An oxide 62 having a thickness ranging from about 250 Å to about 1,000 Å is formed on portions 50 and 52 of polysilicon layer 46. By way of example, oxide 62 has a thickness of about 670 Å.

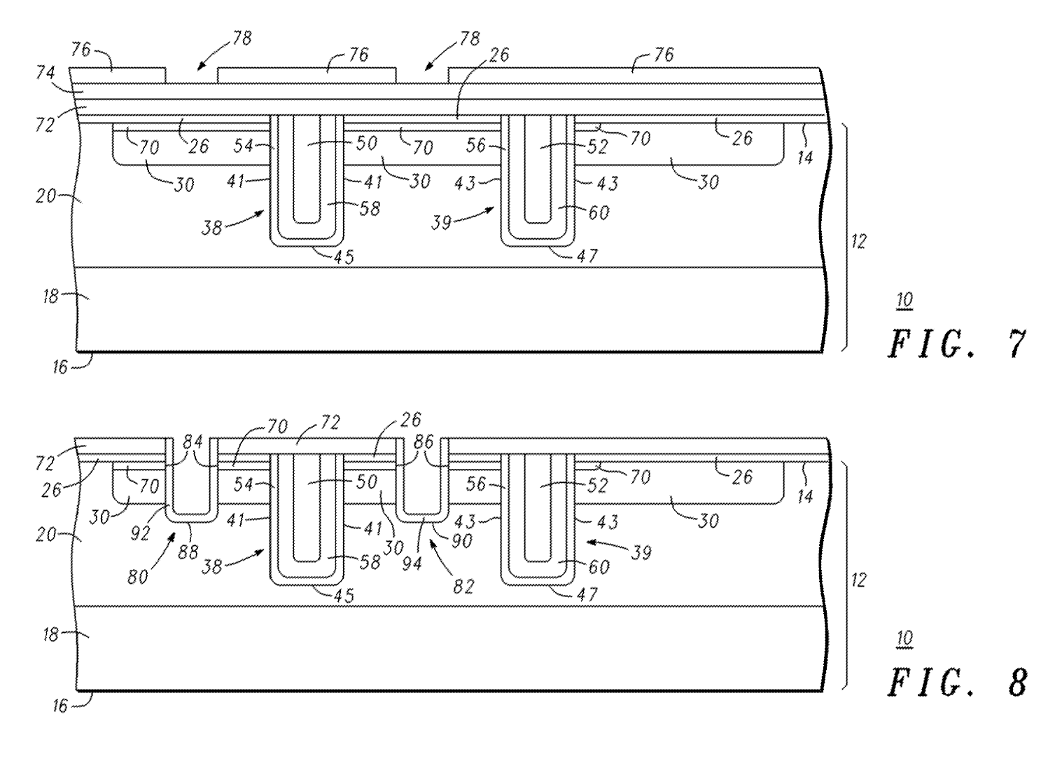

Referring now to FIG. 6, protective layer 28 is removed using, for example, a wet etch suitable for removing a silicon nitride layer. Portions 50 and 52 remain in trenches 38 and 39, respectively. It should be noted that for the sake of clarity, the upper surface of dielectric layer 26, portions 54 and 56 of dielectric layer 40, portions 58 and 60 of dielectric layer 42, and portions 50 and 52 of polysilicon layer 46 are shown as being planar. However, this is not a limitation of the present invention, i.e., the surfaces may be non-planar. A layer of photoresist is patterned over dielectric layer 26, portions 54 and 56 of dielectric layer 40, portions 58 and 60 of dielectric layer 42, and portions 50 and 52 of polysilicon layer 46 to form a masking structure 64 having openings 66 that expose portions of dielectric layer 26 that are over doped regions 30. Masking structure 64 is also referred to as a mask. Doped layers are formed in doped regions 30 by implanting an impurity material of N-type conductivity such as, for example, phosphorus or arsenic at a dose ranging from about 1×10¹⁴ atoms/cm² to about 5×10¹⁶ atoms/cm² and an implant energy ranging from about 20 keV to about 500 keV into doped regions 30 to form source regions 70. Source regions 70 extend from surface 14 into epitaxial layer 20 a vertical distance that is less than the vertical distance that doped regions 30 extend into epitaxial layer 20.

Referring now to FIG. 7, masking structure 64 is removed and a layer of dielectric material 72 having a thickness ranging from about 500 Å to about 2,000 Å is formed over dielectric layer 26, portions 54 and 56 of dielectric layer 40, portions 58 and 60 of dielectric layer 42, and portions 50 and 52 of polysilicon layer 46. A layer of dielectric material 74 having a thickness ranging from about 1,000 Å to about 5,000 Å is formed over dielectric layer 72. Dielectric layer 74 serves as a hardmask. By way of example dielectric layer 72 is a silicon nitride layer and dielectric layer 74 is a TEOS layer. A layer of photoresist is patterned over dielectric layer 74 to form a masking structure 76 having openings 78 that expose portions of dielectric layer 74 that are over doped regions 30. Masking structure 76 is also referred to as a mask.

Referring now to FIG. 8, the portions of dielectric layer 74 that are exposed by openings 78 and the portions of dielectric layers 72 and 26 that are below the exposed portions of hardmask layer 74 are removed thereby exposing portions of surface 14. Masking structure 76 is removed. Techniques for removing the portions of layers 74, 72, and 26 and masking structure 76 are known to one skilled in the art. Trenches 80 and 82 having sidewalls 84 and 86, and floors 88 and 90, respectively, are formed in epitaxial layer 20. Trench 80 extends into the portions of source region 70 and doped region 30 that are adjacent to and laterally spaced apart from trench 38 and trench 82 extends into the portions of source region 70 and doped region 30 that are between trenches 38 and 39. Preferably, trenches 80 and 82 extend from surface 14 through source regions 70, doped region 30, and into epitaxial layer 20. Because gate structures are formed from trenches 80 and 82, they are also referred to as gate trenches. After formation of trenches 80 and 82, the remaining portions of hardmask 76 and dielectric layer 74 are removed using, for example, a wet etching technique. It should be noted that the removal of dielectric layer 74 may include the formation of a sacrificial oxide layer within trenches 80 and 82, wherein the sacrificial oxide layer is removed after the removal of dielectric layer 74.

A layer of dielectric material having a thickness ranging from about 100 Å to about 1,000 Å is formed from or on the portions of sidewalls 84 and 86 and floors 88 and 90 of trenches 80 and 82, respectively. The portion of the layer of dielectric material in trench 80 is identified by reference number 92 and the portion of the layer of dielectric material in trench 82 is identified by reference number 94. In accordance with an embodiment of the present invention, dielectric layers 92 and 94 are oxide layers that serve as a gate oxide for semiconductor component 10.

Referring now to FIG. 9, an electrically conductive material such as, for example, a doped layer of semiconductor material 96 having a dopant or impurity material concentration ranging from about 1×10¹⁹ atoms/cm³ to about 1×10²¹ atoms/cm³ and a thickness ranging from about 1,000 Å to about 8,000 Å is formed on gate oxide layers 92 and 94, dielectric layer 26, portions 54 and 56 of dielectric layer 40, portions 58 and 60 of dielectric layer 42, and portions 50 and 52 of polysilicon layer 46. In accordance with an embodiment of the present invention, conductive layer 96 is a polysilicon layer having a thickness of about 3,500 Å and an impurity material concentration of about 2×10²⁰ atoms/cm³.

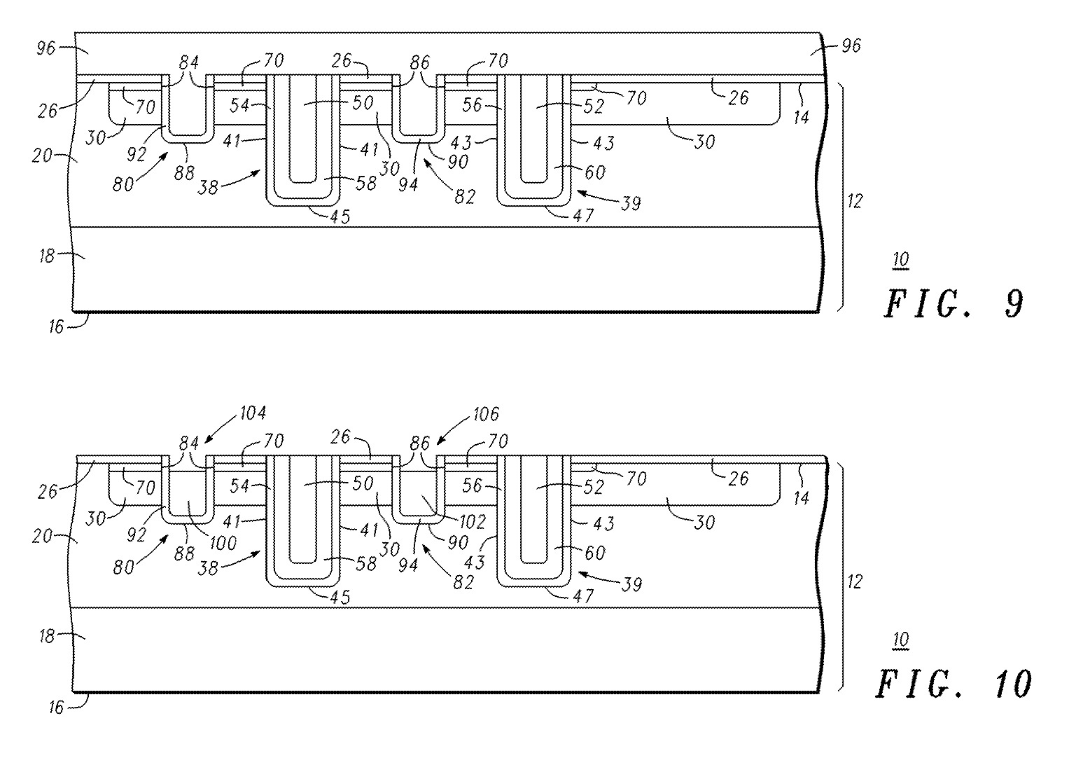

Referring now to FIG. 10, polysilicon layer 96 is etched and recessed within trenches 80 and 82 using, for example, a reactive ion etch process. Preferably, the recessed portions of polysilicon layer 96 and the lower boundary of source regions 70 are at about the same distance from surface 14. In other words, the upper boundaries of portions 100 and 102 of polysilicon layer 96 are at about the same level as the lower boundary of source regions 70. However, it should be noted that the distance the recessed portions extend into trenches 80 and 82 is not a limitation of the present invention. Dielectric layer 26 serves as an etch stop layer. Portions 100 and 102 of polysilicon layer 96 remain in trenches 80 and 82, respectively, and form gate conductors. Gate oxide layer 92 and gate conductor 100 in trench 80 form a gate structure 104 and gate oxide layer 94 and gate conductor 102 in trench 82 form a gate structure 106. In accordance with an embodiment, polysilicon layer 96 can be etched and recessed using a photolithographic technique to leave a portion of gate conductors 100 and 102 on dielectric layer 26. Alternatively, polysilicon layer 96 can be etched and recessed using a non-photolithographic technique so that portions of gate conductors 100 and 102 may or may not remain on dielectric layer 26.

Referring now to FIG. 11, a layer of dielectric material 110 is formed over portions 54 and 56 of dielectric layer 40, portions 58 and 60 of dielectric layer 42, portions 50 and 52 of polysilicon layer 46, and portions 100 and 102 of polysilicon layer 96. Dielectric layer 110 typically is referred to as an interlayer dielectric (“ILDO”) layer. A layer of photoresist is formed on ILDO layer 110 and patterned to form a masking structure 112 having openings 114 and 116 that expose portions of ILDO layer 110 that are over trenches 38 and 39 and portions of ILDO layer 110 that are over portions of dielectric layer 26 that are laterally adjacent to trenches 38 and 39.

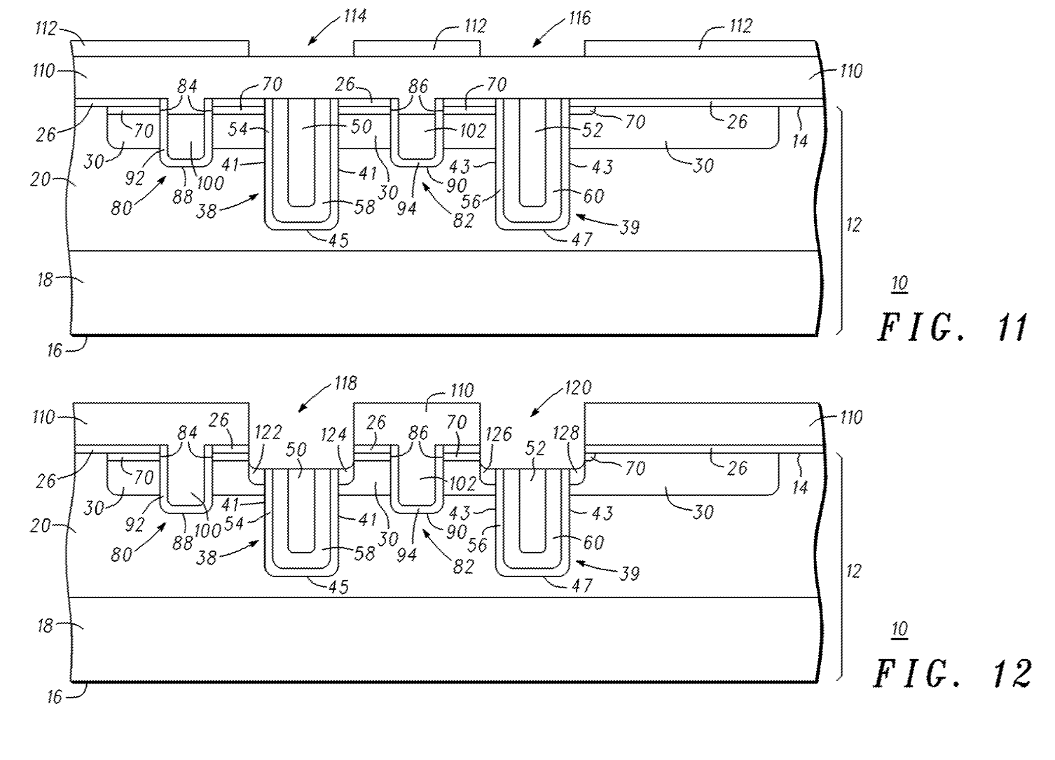

Referring now to FIG. 12, the portions of ILDO layer 110 that are exposed by openings 114 and 116 are anisotropically etched using for example, a reactive ion etch to form openings 118 and 120 that extend into portions 54 and 56 of dielectric layer 40, portions 58 and 60 of dielectric layer 42, and portions 50 and 52 of polysilicon layer 46. An impurity material of P-type conductivity such as, for example, boron or indium may be implanted into the portions of doped regions 30 that are adjacent to trenches 38 and 39. The impurity material implanted through openings 118 and 120 form contact enhancement regions 122, 124, 126, and 128, wherein contact enhancement regions 122 and 124 are adjacent to trench 38 and contact enhancement regions 126 and 128 are adjacent to trench 39. By way of example, the impurity material is implanted at a dose ranging from about 1×10¹⁴ atoms/cm² to about 5×10¹⁶ atoms/cm² and an implant energy ranging from about 10 keV to about 100 keV. Masking structure 112 is removed and epitaxial layer 20 is annealed using a rapid thermal anneal technique.

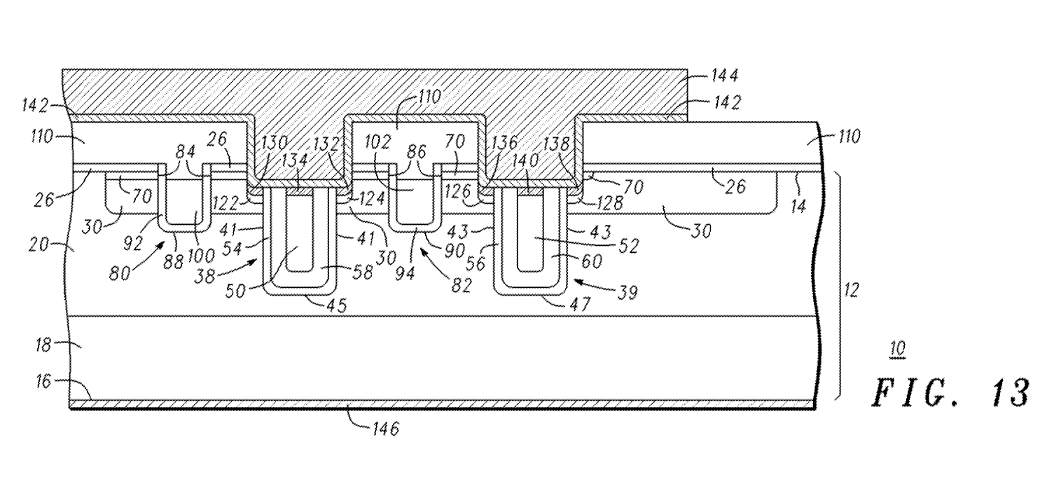

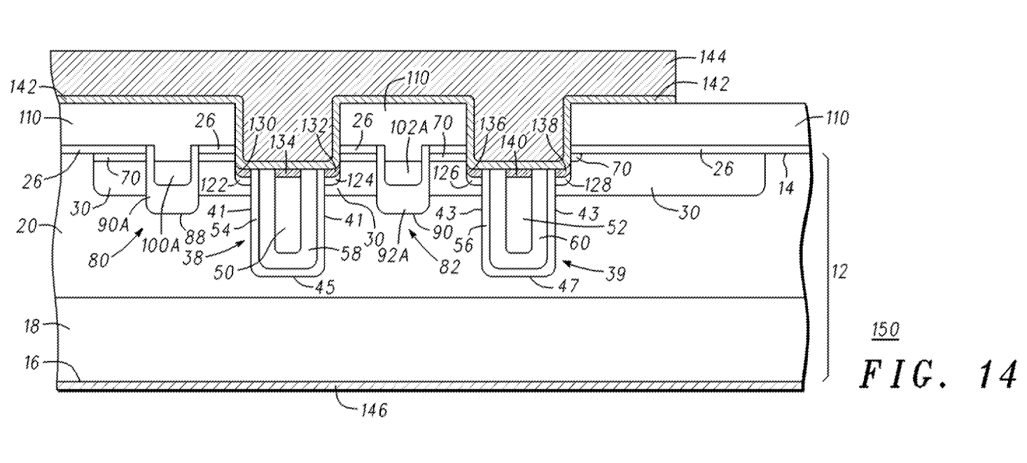

Referring now to FIG. 13, a layer of refractory metal (not shown) is conformally deposited over portions of doped regions 30, over contact enhancement regions 122-128, over portions 50 and 52 of polysilicon layer 46, and over dielectric layer 110. By way of example, the refractory metal is titanium having a thickness ranging from about 100 Å to about 1,000 Å. The refractory metal is heated to a temperature ranging from about 350° C. to about 700° C. The heat treatment causes the titanium to react with the silicon to form titanium silicide in all regions in which the titanium is in contact with silicon or polysilicon. Thus, titanium silicide layers 130 and 132 are formed from contact enhancement regions 122 and 124, respectively, a titanium silicide layer 134 is formed from portion 50 of polysilicon layer 46, titanium silicide layers 136 and 138 are formed from contact enhancement regions 126 and 128, respectively, and a titanium silicide layer 140 is formed from portion 52 of polysilicon layer 46.

A barrier layer is formed in contact with titanium silicide layers 130-140 and over ILD layer 110. Suitable materials for the barrier layer include titanium nitride, titanium tungsten, or the like. A metal layer such as, for example, aluminum, is formed in contact with the barrier layer. A layer of photoresist (not shown) is formed on the metal layer and patterned to expose portions of the metal layer. The exposed portions of the metal layer and the portions of the barrier layer below the exposed portions of the metal layer are etched to form electrical conductors. More particularly, silicide layers 130-140, portion 142 of the barrier layer, and a portion 144 of the metal layer cooperate to form a source contact. A conductor 146 is formed in contact with surface 16 and serves as a drain contact for power FET 10. Although a bottom-side drain contact is shown in FIG. 13, the present invention is not limited in this regard. For example, the drain electrode can be formed from the top side. Suitable metallization systems for conductor 146 include a gold alloy, titanium-nickel-gold, titanium-nickel-silver, or the like. It should be further understood that the type of semiconductor device manufactured from semiconductor material 12 is not limited to being a power FET or a trench FET.

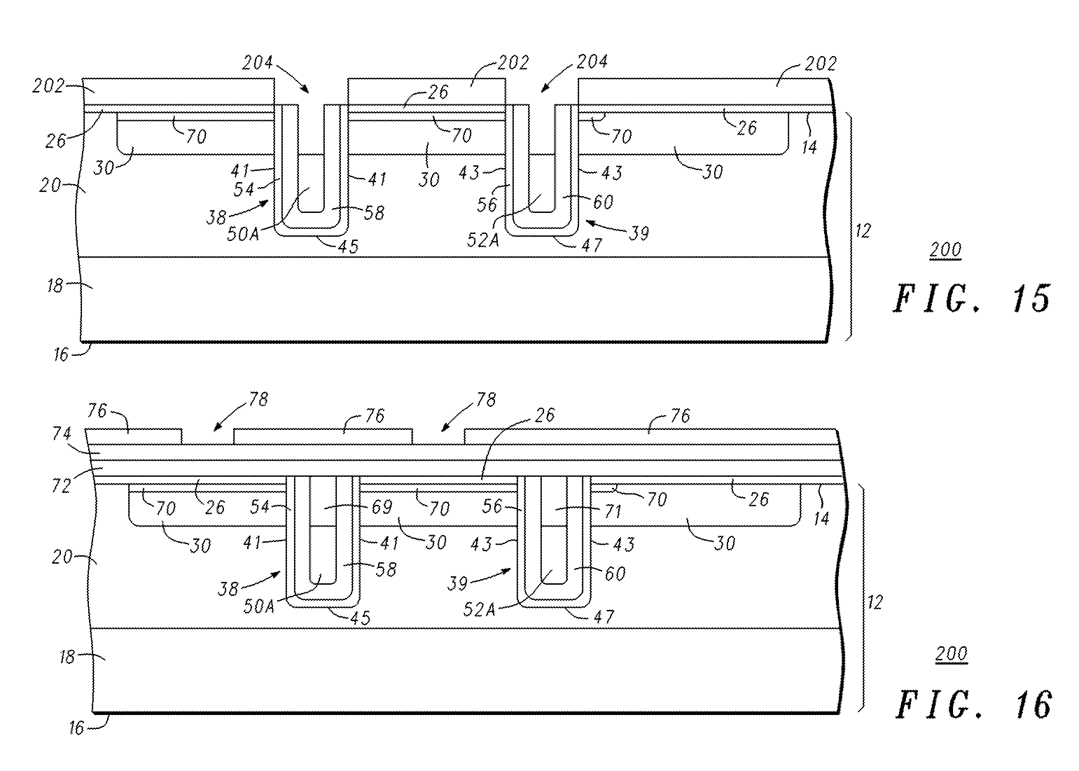

FIG. 14 is a cross-sectional view of a semiconductor component 150 in accordance with another embodiment of the present invention. Like semiconductor component 10, semiconductor component 150 may include field plate trenches 38 and 39 formed in a semiconductor material 12 that comprises epitaxial layer 20 formed on semiconductor substrate 18. Doped regions 30 are formed in epitaxial layer 20 and doped regions 70 are formed in doped regions 30. Field plates 50 and 52 are formed in field plate trenches 38 and 39, respectively. Silicide layers 130-140, portion 142 of the barrier layer, and a portion 144 of the metal layer cooperate to form a source contact. A conductor 146 is formed in contact with surface 16 and serves as a drain contact for power FET 150. Gate trenches 80 and 82 are formed in semiconductor material 12. A gate oxide or gate oxide layer 90A is formed in gate trench 80 and a gate oxide or gate oxide layer 92A is formed in gate trench 82. Gate oxide layers 90A and 92A are thicker near the bottom of trenches 80 and 82, respectively, than along their sidewalls near the tops of trenches 80 and 82. Gate conductors 100A and 102A are formed over gate oxide layers 90A and 92A in gate trenches 80 and 82, respectively.

FIG. 15 is a cross-sectional view of a semiconductor component 200 at an intermediate stage of manufacture in accordance with another embodiment of the present invention. The process steps described with reference to FIG. 15 continue from those described in FIGS. 1-6. Accordingly, FIG. 15 is a cross-sectional view of a semiconductor component of FIG. 6 at a later stage of manufacture except that the reference number associated with the semiconductor component of FIG. 15 is 200 rather than 10 as shown and described in FIGS. 1-6. Referring now to FIG. 15, masking structure 64 is removed and a layer of photoresist is patterned over dielectric layer 26, portions 54 and 56 of dielectric layer 40, portions 58 and 60 of dielectric layer 42, and portions 50 and 52 of polysilicon layer 46 to form a masking structure 202 having openings 204 that expose portions 54 and 56 of dielectric layer 40, portions 58 and 60 of dielectric layer 42, and portions 50 and 52 of polysilicon layer 46. Masking structure 202 is also referred to as a mask. Portions 50 and 52 are etched and recessed using, for example, a reactive ion etch process. Preferably, the recessed portions extend a distance into trenches 38 and 39 that is at least as great as the distance that doped regions 30 extend into epitaxial layer 20. In accordance with an embodiment, portions 50 and 52 can be etched and recessed using a photolithographic technique to leave portions 50A and 52A, respectively in trenches 38 and 39. Alternatively, portions 50 and 52 can be etched and recessed using non-photolithographic techniques.

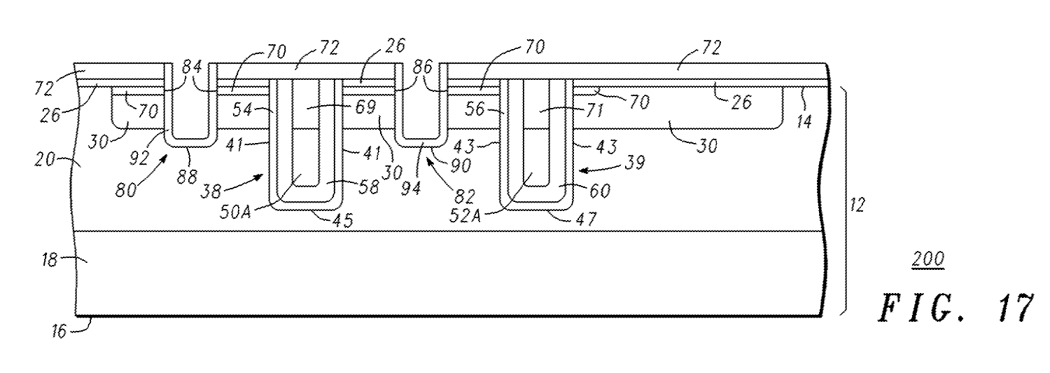

Referring now to FIG. 16, masking structure 202 is removed and a dielectric plugs 69 and 71 are formed on portions 50A and 52A. The material for dielectric plugs may be oxide, nitride, or the like. A layer of dielectric material 72 having a thickness ranging from about 500 Å to about 2,000 Å is formed over dielectric layer 26, portions 54 and 56 of dielectric layer 40, portions 58 and 60 of dielectric layer 42, and dielectric plugs 69 and 71. A layer of dielectric material 74 having a thickness ranging from about 1,000 Å to about 5,000 Å is formed over dielectric layer 72. Dielectric layer 74 serves as a hardmask. By way of example dielectric layer 72 is a silicon nitride layer and dielectric layer 74 is a TEOS layer. A layer of photoresist is patterned over dielectric layer 74 to form a masking structure 76 having openings 78 that expose portions of dielectric layer 74 that are over doped regions 30. Masking structure 76 is also referred to as a mask.

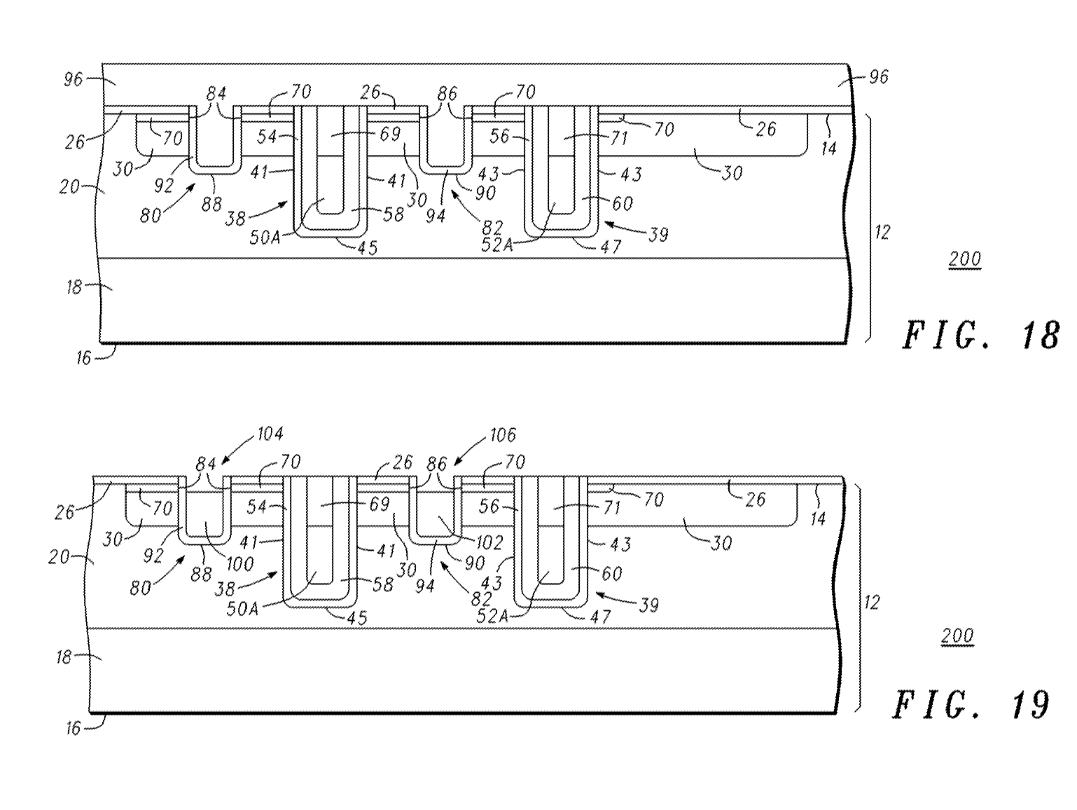

Referring now to FIG. 17, the portions of dielectric layer 74 that are exposed by openings 78 and the portions of dielectric layers 72 and 26 that are below the exposed portions of hardmask layer 74 are removed thereby exposing portions of surface 14. Masking structure 76 is removed. Techniques for removing the portions of layers 74, 72, and 26 and masking structure 76 are known to one skilled in the art. Trenches 80 and 82 having sidewalls 84 and 86, and floors 88 and 90, respectively, are formed in epitaxial layer 20. Trench 80 extends into the portions of source region 70 and doped region 30 that are adjacent to and laterally spaced apart from trench 38 and trench 82 extends into the portions of source region 70 and doped region 30 that are between trenches 38 and 39. Preferably, trenches 80 and 82 extend from surface 14 through source regions 70, doped region 30, and into epitaxial layer 20. Because gate structures are formed from trenches 80 and 82, they are also referred to as gate trenches. After formation of trenches 80 and 82, the remaining portions of hardmask 76 and dielectric layer 74 are removed using, for example, a wet etching technique. It should be noted that the removal of dielectric layer 74 may include the formation of a sacrificial oxide layer within trenches 80 and 82, wherein the sacrificial oxide layer is removed after the removal of dielectric layer 74.

A layer of dielectric material having a thickness ranging from about 100 Å to about 1,000 Å is formed from or on the portions of sidewalls 84 and 86 and floors 88 and 90 of trenches 80 and 82, respectively. The portion of the layer of dielectric material in trench 80 is identified by reference number 92 and the portion of the layer of dielectric material in trench 82 is identified by reference number 94. In accordance with an embodiment of the present invention, dielectric layers 92 and 94 are oxide layers that serve as a gate oxide for semiconductor component 10.

Referring now to FIG. 18, an electrically conductive material such as, for example, a doped layer of semiconductor material 96 having a dopant or impurity material concentration ranging from about 1×10¹⁹ atoms/cm³ to about 1×10²¹ atoms/cm³ and a thickness ranging from about 1,000 Å to about 8,000 Å, is formed on gate oxide layers 92 and 94, dielectric layer 26, portions 54 and 56 of dielectric layer 40, portions 58 and 60 of dielectric layer 42, and portions 50 and 52 of polysilicon layer 46. In accordance with an embodiment of the present invention, conductive layer 96 is a polysilicon layer having a thickness of about 3,500 Å and an impurity material concentration of about 2×10²⁰ atoms/cm³.

Referring now to FIG. 19, polysilicon layer 96 is etched and recessed within trenches 80 and 82 using, for example, a reactive ion etch process. Preferably, the recessed portions of polysilicon layer 96 and the lower boundary of source regions 70 are at about the same distance from surface 14. In other words, the upper boundaries of portions 100 and 102 of polysilicon layer 96 are at about the same level as the lower boundary of source regions 70. However, it should be noted that the distance the recessed portions extend into trenches 80 and 82 is not a limitation of the present invention. Dielectric layer 26 serves as an etch stop layer. Portions 100 and 102 of polysilicon layer 96 remain in trenches 80 and 82, respectively, and form gate conductors. Gate oxide layer 92 and gate conductor 100 in trench 80 form a gate structure 104 and gate oxide layer 94 and gate conductor 102 in trench 82 form a gate structure 106. In accordance with an embodiment, polysilicon layer 96 can be etched and recessed using a photolithographic technique to leave a portion of gate conductors 100 and 102 on dielectric layer 26. Alternatively, polysilicon layer 96 can be etched and recessed using a non-photolithographic technique so that portions of gate conductors 100 and 102 may or may not remain on dielectric layer 26.

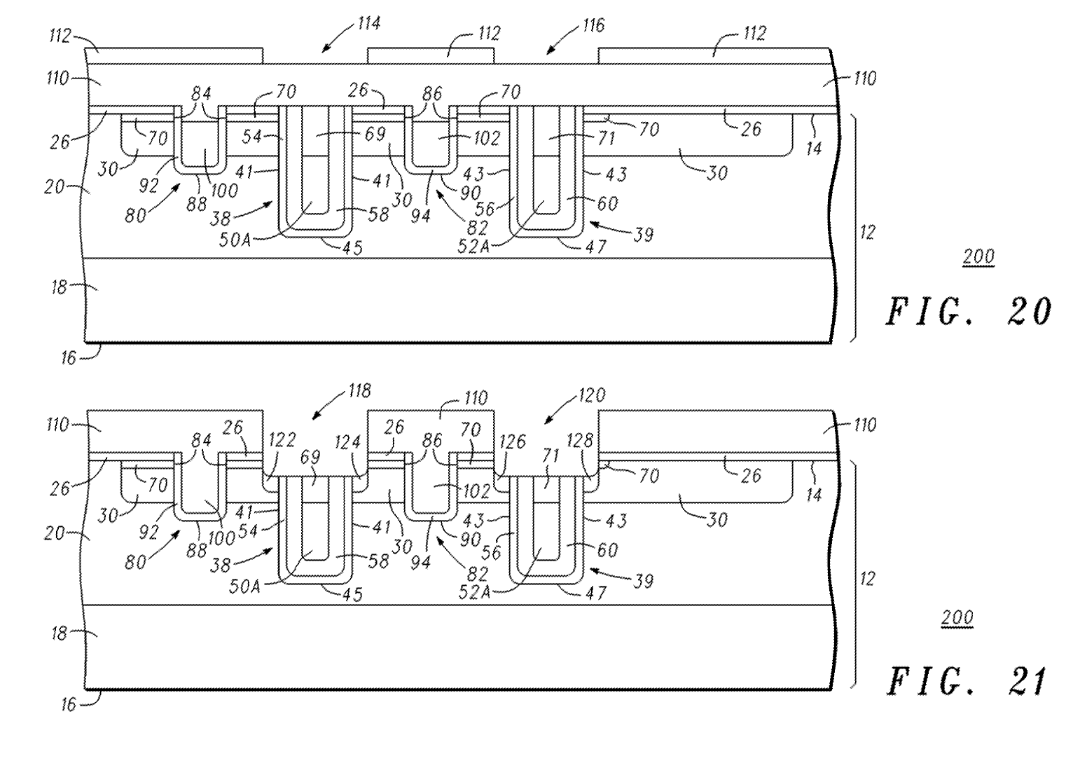

Referring now to FIG. 20, a layer of dielectric material 110 is formed over portions 54 and 56 of dielectric layer 40, portions 58 and 60 of dielectric layer 42, portions 50 and 52 of polysilicon layer 46, and portions 100 and 102 of polysilicon layer 96. Dielectric layer 110 typically is referred to as an interlayer dielectric (“ILDO”) layer. A layer of photoresist is formed on ILDO layer 110 and patterned to form a masking structure 112 having openings 114 and 116 that expose portions of ILDO layer 110 that are over trenches 38 and 39 and portions of ILDO layer 110 that are over the portions of dielectric layer 26 that are laterally adjacent to trenches 38 and 39 and over gate electrodes 100 and 102.

Referring now to FIG. 21, the portions of ILDO layer 110 that are exposed by openings 114 and 116 are anisotropically etched using for example, a reactive ion etch to form openings 118 and 120 that extend into portions 54 and 56 of dielectric layer 40, portions 58 and 60 of dielectric layer 42, and dielectric plugs 69 and 71. An impurity material of P-type conductivity such as, for example, boron or indium may be implanted into the portions of doped regions 30 that are adjacent to trenches 38 and 39. The impurity material implanted through openings 118 and 120 form contact enhancement regions 122, 124, 126, and 128, wherein contact enhancement regions 122 and 124 are adjacent to trench 38 and contact enhancement regions 126 and 128 are adjacent to trench 39. By way of example, the impurity material is implanted at a dose ranging from about 1×10¹⁴ atoms/cm² to about 5×10¹⁶ atoms/cm² and an implant energy ranging from about 10 keV to about 100 keV. Masking structure 112 is removed and epitaxial layer 20 is annealed using a rapid thermal anneal technique.

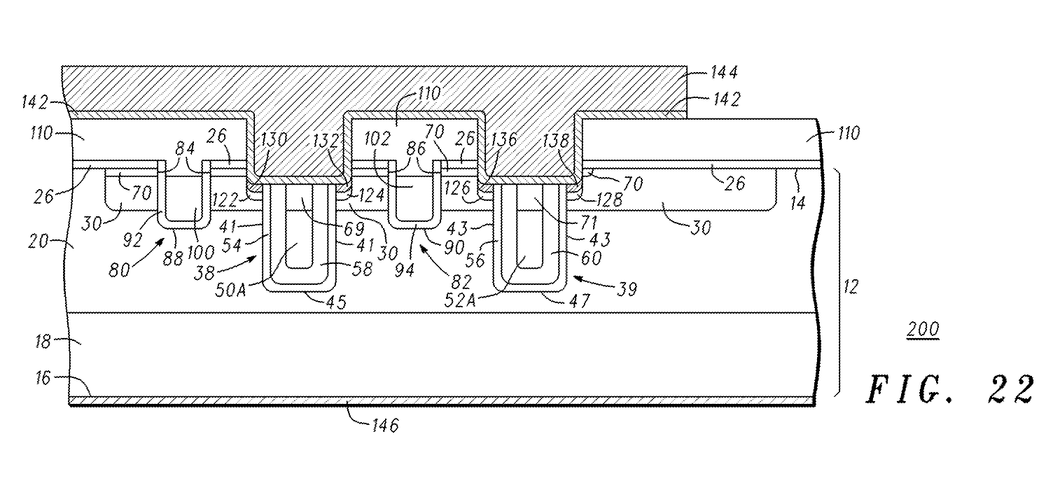

Referring now to FIG. 22, a layer of refractory metal (not shown) is conformally deposited over portions of doped regions 30, over contact enhancement regions 122-128, over dielectric plugs 69 and 71, and over dielectric layer 110. By way of example, the refractory metal is titanium having a thickness ranging from about 100 Å to about 1,000 Å. The refractory metal is heated to a temperature ranging from about 350° C. to about 700° C. The heat treatment causes the titanium to react with the silicon to form titanium silicide in all regions in which the titanium is in contact with silicon or polysilicon. Thus, titanium silicide layers 130 and 132 are formed from contact enhancement regions 122 and 124, respectively, and titanium silicide layers 136 and 138 are formed from contact enhancement regions 126 and 128, respectively.

A barrier layer is formed in contact with titanium silicide layers 130, 132, 136, and 138 and over ILD layer 110. Suitable materials for the barrier layer include titanium nitride, titanium tungsten, or the like. A metal layer such as, for example, aluminum, is formed in contact with the barrier layer. A layer of photoresist (not shown) is formed on the metal layer and patterned to expose portions of the metal layer. The exposed portions of the metal layer and the portions of the barrier layer below the exposed portions of the metal layer are etched to form electrical conductors. More particularly, silicide layers 130, 132, 136, and 138, portion 142 of the barrier layer, and a portion 144 of the metal layer cooperate to form a portion of a source contact. A conductor 146 is formed in contact with surface 16 and serves as a drain contact for power FET 10. Although a bottom-side drain contact is shown in FIG. 22, the present invention is not limited in this regard. For example, the drain electrode can be formed from the top side. Suitable metallization systems for conductor 146 include a gold alloy, titanium-nickel-gold, titanium-nickel-silver, or the like. It should be further understood that the type of semiconductor device manufactured from semiconductor material 12 is not limited to being a power FET or a trench FET.

Although certain preferred embodiments and methods have been disclosed herein, it will be apparent from the foregoing disclosure to those skilled in the art that variations and modifications of such embodiments and methods may be made without departing from the spirit and scope of the invention. For example, the semiconductor devices may be vertical devices or lateral devices. It is intended that the invention shall be limited only to the extent required by the appended claims and the rules and principles of applicable law.

What is claimed is:

1. A method for manufacturing a semiconductor component, comprising:
providing a semiconductor material having first and second opposing surfaces;
forming first and second trenches in the semiconductor material, wherein the first and second trenches have at least one sidewall and extend from the first surface into the semiconductor material a first distance;
forming a dielectric material in the first and second trenches;
forming a semiconductor material in the first and second trenches, the dielectric material in the first trench between the semiconductor material in the first trench and the at least one sidewall of the first trench and the dielectric material in the second trench between the semiconductor material in the second trench and the at least one sidewall of the second trench; and
forming a gate structure between the first and second trenches by:
forming a third trench in the semiconductor material, the third trench having at least one sidewall and extending from the first surface into the semiconductor material a second distance;
forming a gate dielectric in the third trench; and
forming a semiconductor material in the third trench, wherein the gate dielectric is between the at least one sidewall of the third trench and the semiconductor material in the third trench.

2. The method of claim 1, wherein the first distance is greater than the second distance.

3. The method of claim 1, wherein providing the semiconductor material having first and second opposing surfaces includes:
providing a substrate of a first conductivity type and having the second surface; and
forming an epitaxial layer of the first conductivity type on the substrate, wherein the epitaxial layer has the second surface; and further including
forming a first doped region of a second conductivity type in the epitaxial layer.

4. The method of claim 3, wherein the first, second, and third trenches extend from the first surface through the first doped region.

5. The method of claim 4, further including forming a second doped region of the first conductivity type extending from the first surface into the semiconductor material.

6. The method of claim 5, wherein forming the second doped region of the first conductivity type includes forming portions of the second doped region to be adjacent to the first, second, and third trenches.

7. The method of claim 5, wherein forming the second doped region of the first conductivity type includes forming portions of the second doped region to be between the first and second trenches.

8. The method of claim 1, further including forming a conductor in contact with the semiconductor material in the first and second trenches.

9. A method for manufacturing a semiconductor component, comprising:
providing a semiconductor material of a first conductivity type;
forming first and second trenches in the semiconductor material;
forming first and second field plates in the first and second trenches, respectively;
forming a third trench in the semiconductor material, the third trench between the first and second trenches; and
forming a first gate structure in the third trench.

10. The method of claim 9, wherein forming the first and second field plates comprises:
lining the first trench with a first dielectric material;
lining the second trench with a second dielectric material;
forming a first electrically conductive material on the first dielectric material; and
forming second electrically conductive material on the second dielectric material.

11. The method of claim 10, wherein forming the first electrically conductive material and the second electrically conductive material comprises forming polysilicon in the first and second trenches.

12. The method of claim 11, wherein forming the first and second trenches in the semiconductor material includes forming the first and second trenches to extend a first distance into the semiconductor material and forming the third trench includes forming the third trench to extend a second distance into the semiconductor material.

13. The method of claim 12, wherein the second distance is less than the first distance.

14. The method of claim 13, wherein forming the first gate structure in the third trench includes lining the third trench with a gate oxide and forming a gate conductor on the gate oxide.

15. The method of claim 14, wherein lining the third trench with the gate oxide includes forming a portion of the gate oxide on a bottom of the third trench to be thicker than another portion of the gate oxide on sidewalls near a top of the third trench.

16. The method of claim 10, further including:
forming a fourth trench in the semiconductor material, the fourth trench adjacent to and laterally spaced apart from the first trench; and
forming a second gate structure in the fourth trench.

17. The method of claim 16, further including electrically coupling the first field plate to the second field plate.

18. The method of claim 9, further including forming a doped region of a second conductivity type in the semiconductor material of the first conductivity type.

19. A semiconductor component, comprising:
a semiconductor material of a first conductivity type having a major surface;
first and second trenches extending from the major surface into the semiconductor material;
first and second field plates in the first and second trenches, respectively;
a third trench extending from the major surface into the semiconductor material, the third trench between the first and second trenches; and
first gate structure in the third trench.

20. The semiconductor component of claim 19, further including:
a fourth trench extending from the major surface into the semiconductor material, the fourth trench adjacent the first trench; and
a second gate structure in the fourth trench.

21. The semiconductor component of claim 20, wherein
the first and second field plates comprises first and second doped semiconductor materials in the first and second trenches, respectively;
the first gate structure comprises a first dielectric material lining a sidewall and a floor of the third trench and a fourth doped semiconductor material on the first dielectric material; and
the second gate structure comprises a second dielectric material lining a sidewall and a floor of the fourth trench and a fourth doped semiconductor material on the second dielectric material.
